(19) United States
(12) Patent Application Publication
(10) Pub. No.: US 2024/0232468 A1
(43) Pub. Date: Jul. 11, 2024

(54) DEVICE LEAKAGE CURRENT MODEL AND METHOD FOR EXTRACTING THE SAME

(71) Applicant: Shanghai Huali Integrated Circuit Corporation, Shanghai (CN)

(72) Inventors: Qingwen WANG, Shanghai (CN); Yuanyuan WU, Shanghai (CN); Ganbing SHANG, Shanghai (CN)

(21) Appl. No.: 18/465,123

(22) Filed: Sep. 11, 2023

(30) Foreign Application Priority Data
Jan. 7, 2023 (CN) 202310021628.9

(51) Int. Cl. G06F 30/20

(52) U.S. Cl. CPC G06F 30/20

(57) ABSTRACT

A device model for simulating a leakage current of a semiconductor device is disclosed, including a gate structure having a first metal gate and a metal work function layer of the first conductive type. The leakage current of the device model is acquired by multiplying a main function by a first function. The first function is a function of the metal gate boundary proximity effect parameters of the semiconductor device. These parameters influence the metal gate boundary proximity effect on the leakage current in modeling. Also disclosed is a method to extract the device model of leakage current. The device model simulates the influence of the MBE effects via parameter fitting, thereby improving on the device leakage current and the design of more reasonable layouts.

### CROSS-REFERENCES TO RELATED APPLICATIONS

This application claims the priority to Chinese patent application No. 202310021628.9, filed on Jan. 7, 2023, and entitled “DEVICE LEAKAGE CURRENT MODEL AND METHOD FOR EXTRACTING THE”, the disclosure of which is incorporated herein by reference in entirety.

### TECHNICAL FIELD

The present application relates to the field of semiconductor integrated circuit manufacturing, and in particular to a device leakage current model. The present application also relates to a method for extracting the device leakage current model.

### BACKGROUND

As the increasing improvements of process nodes and continuous decreasing of application voltages, low-power designs have become important indicators of acceptable circuit designs. As process nodes advance, a static leakage current has accounted for an increasing proportion of overall power consumption the IC chip. Therefore, it is essential to accurately and comprehensively characterize device leakage current performance. The leakage current which trigger static power consumption in a MOSFET mainly includes: a source-to-drain subthreshold leakage current, a gate leakage current, and a gate-induced drain leakage (GIDL) current which occurs in a gate-to-drain crossover region. Among these leakage currents, the GIDL current is a dominating one when the MOSFET device in the circuit is turned off or is in a waiting state. Therefore, it is important for high-performance low-quiescent-power-dissipation designs to accurately and comprehensively characterize a GIDL leakage current model.

Referring to FIG. 1, it is an architectural view 101 of an existing device leakage current model, the equation of which is:

$$Idoff = f ( w , l , vgs , T ) ; \qquad ( 1 )$$

where Idoff indicates a device leakage current, mainly the GIDL leakage current: f(w,l,vgs,T) shows the function of the GIDL leakage current, w indicates the width of a channel region of the semiconductor device, l indicates the length of the channel region of the semiconductor device, vgs indicates the gate to source voltage of the semiconductor device, and T indicates the operating temperature of the semiconductor device. It can be seen that w, l, vgs, and T are the structural and operational parameters of the semiconductor device itself.

At present, a large number of stress enhancement techniques are introduced in advanced processes to increase the device carrier mobility, which leads to an increasing influence of the surrounding environment on the electrical characteristics of the device itself, further significantly influencing the GIDL current of the device. In the 28-nm CMOS process node, the replacement metal gate (RMG) process is widely used in high-k metal gate (HKMG) devices, and different metal gate function materials used to regulate NMOS/PMOS threshold voltages lead to the N/P metal gate boundary proximity effect (Metal Boundary Effect, MBE). MBE refers to corresponding changes in GIDL currents caused by the influence of device threshold voltages and channel current characteristics caused by the changes in metal boundary functions of different types of transistors, i.e., N type and P type. Existing GIDL SPICE models do not provide a solution for this MBE effect.

### BRIEF SUMMARY

According to some embodiments in this application, a device leakage current model provided by the present application simulates a leakage current of a semiconductor device, the gate structure of the semiconductor device has a first metal gate, and the first metal gate has a metal function layer of the first conductive type.

The leakage current of the device leakage current model is formed by multiplying a main function by a first function.

The first function is a function formed by the metal gate boundary proximity effect parameters of the semiconductor device for modeling the influence of the metal gate boundary proximity effect on the leakage current.

In some cases, the metal gate boundary proximity effect parameters include a first spacing and a second spacing.

The semiconductor device is formed in a first active region, and a channel region is formed in the first active region covered by the first metal gate.

The channel region includes a first length edge, a second length edge and two width edges.

The length direction of the first metal gate is the same as the width edge direction of the channel region.

The first metal gate further extends along the length direction at both sides into the first active region, and the first metal gate has a first boundary and a second boundary outside the first active region.

The first boundary is the boundary between the first conductive type metal work function layer of the first metal gate and a second conductive type metal work function layer of a first adjacent metal gate.

The second boundary is the boundary between the first conductive type metal work function layer of the first metal gate and a second conductive type metal work function layer of a second adjacent metal gate.

The first boundary is adjacent to the first length edge, and the first spacing is the distance between the first boundary and the first length edge.

The second boundary is adjacent to the second length edge, and the second spacing is the distance between the second boundary and the second length edge.

In some cases, the parameters of the first function further include the length and width of the channel region.

In some cases, the equation of the first function is:

$$f 1 ( SPMT , SPMB ) = \frac{γ 1}{pwr ( SPMT , α1 )} * [ A 1 + \frac{B 1}{pwr ( L , b 1 )} + \frac{C 1}{pwr ( W , c 1 )} + \frac{D 1}{pwr ( W * L , d 1 )} ] + \frac{γ 2}{pwr ( SPMB , α2 )} * [ A 2 + \frac{B 2}{pwr ( L , b 2 )} + \frac{C 2}{pwr ( W , c 2 )} + \frac{D 2}{pwr ( W * L , d 2 )} ] ;$$

where f1 ( ) indicates the first function; pwr ( ) indicates a power function;
SPMT indicates the first spacing, and SPMB indicates the second spacing;
W indicates the width of the channel region, and L indicates the length of the channel region; and
γ1, α1, A1, B1, b1, C1, c1, D1, d1, γ2, a2, A2, B2, b2, C2, c2, D2, d2 are all fitting parameters.

In some cases, the main function of the device leakage current model is a GIDL leakage current function: and the parameters of the GIDL leakage current function include: the width and length of the channel region, a gate source voltage and a temperature.

In some cases, each of the fitting parameters of the first function is obtained by performing parameter fitting for a leakage current curve formed by the device leakage current model and an actual measured leakage current curve by varying the first spacing and the second spacing, provided that the main function remains unchanged.

In some cases, the first spacing and the second spacing are modified in a layout design.

To solve the above technical problem, the present application provides a method for extracting a device leakage current model, wherein the device leakage current model is used to simulate a leakage current of a semiconductor device, a first metal gate is used for the gate structure of the semiconductor device, and the first metal gate has a first conductive type metal function layer: including the steps of:
step I. setting the leakage current of the device leakage current model by multiplying a main function by a first function, wherein the first function is a function including the metal gate boundary proximity effect parameters of the semiconductor device, herein the parameters influence the metal gate boundary proximity effect on the leakage current in the model;
step II. performing parameter fitting for the main function by using the semiconductor device unaffected by the metal gate boundary proximity effect: and
step III. performing parameter fitting for the first function to obtain the fitted parameters of the first function by varying the metal gate boundary proximity effect parameters of the semiconductor device while keeping the main function unchanged.

In some cases, the metal gate boundary proximity effect parameters include a first spacing and a second spacing.

The semiconductor device is formed in the first active region, and a channel region is formed in the first active region covered by the first metal gate.

The channel region includes a first length edge, a second length edge and two width edges.

The length direction of the first metal gate is the same as the width edge direction of the channel region.

The first metal gate further extends along the length direction of at both sides into the first active region, and the first metal gate has a first boundary and a second boundary outside the first active region.

The first boundary is the boundary between the first conductive type metal work function layer of the first metal gate and a second conductive type metal work function layer of a first adjacent metal gate.

The second boundary is the boundary between the first conductive type metal work function layer of the first metal gate and a second conductive type metal work function layer of a second adjacent metal gate.

The first boundary is adjacent to the first length edge, and the first spacing is the distance between the first boundary and the first length edge.

The second boundary is adjacent to the second length edge, and the second spacing is the distance between the second boundary and the second length edge.

In some cases, the parameters of the first function further include the length and width of the channel region.

In some cases, the equation of the first function is:

$$f 1 ( SPMT , SPMB ) = \frac{γ 1}{pwr ( SPMT , α1 )} * [ A 1 + \frac{B 1}{pwr ( L , b 1 )} + \frac{C 1}{pwr ( W , c 1 )} + \frac{D 1}{pwr ( W * L , d 1 )} ] + \frac{γ 2}{pwr ( SPMB , α2 )} * [ A 2 + \frac{B 2}{pwr ( L , b 2 )} + \frac{C 2}{pwr ( W , c 2 )} + \frac{D 2}{pwr ( W * L , d 2 )} ] ;$$

where f1 ( ) indicates the first function; pwr ( ) indicates a power function;
SPMT indicates the first spacing, and SPMB indicates the second spacing;
W indicates the width of the channel region, and L indicates the length of the channel region; and
γ1, α1, A1, B1, b1, C1, c1, D1, d1, γ2, α2, A2, B2, b2, C2, c2, D2, d2 are all fitting parameters.

In some cases, the main function of the device leakage current model is a GIDL leakage current function; and the parameters of the GIDL leakage current function include: the width and length of the channel region, a gate source voltage and a temperature.

In some cases, in step III, each of the fitting parameters of the first function is obtained by performing parameter fitting for a leakage current curve formed by the device leakage current model and an actual measured leakage current curve by varying the first spacing and the second spacing.

In some cases, the first spacing and the second spacing are modified in a layout design.

In some cases, after step III is completed, the step of validating the device leakage current model is also included.

In the present application, when MBE parameters are changed, the influence of such change on a leakage current can be accurately simulated by adding a product term consisting of a first function, a function formed by MBE parameters of a semiconductor device, on the basis of a main function of a leakage current of a device leakage current model. Thus, in the present application, the influence of the MEB effect on the leakage current can be simulated, thus improving the model fitting accuracy.

The MBE parameters of the present application are mainly the spacing between a metal gate boundary and a channel region, i.e., the first spacing and the second spacing, and thus, the present application can achieve more accurate modeling of the leakage current for various MBE parameter sizes and can better reflect actual circuit characteristics of a device.

The application can also achieve a more reasonable layout design on the basis of the device leakage current model.

### BRIEF DESCRIPTION OF THE DRAWINGS

The present application is further described in detail below in conjunction with the figures and specific embodiments:

FIG. 1 shows an architectural view of an existing device leakage current model:

FIG. 2 shows a layout of a semiconductor device according to an embodiment of the present application:

FIG. 3 shows the device leakage current model according to an embodiment of the present application:

FIG. 4 shows the first function of a device leakage current model according to an embodiment of the present application:

FIG. 5 is a flow chart of a method for extracting a model of the device leakage current according to an embodiment of the present application;

FIG. 6A shows leakage current fitting curves using the existing device leakage current model: and

FIG. 6B shows leakage current fitting curves using the device leakage current model according to an embodiment of the present application.

### DETAILED DESCRIPTION OF THE DISCLOSURE

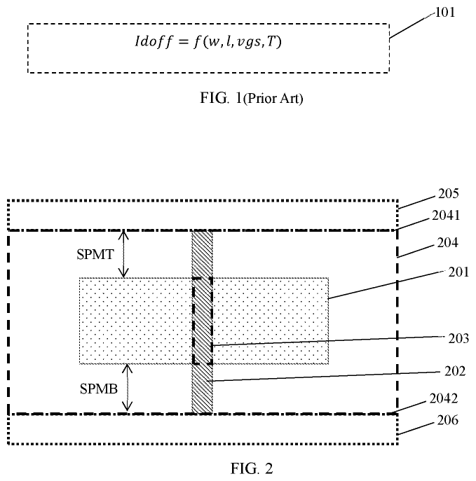

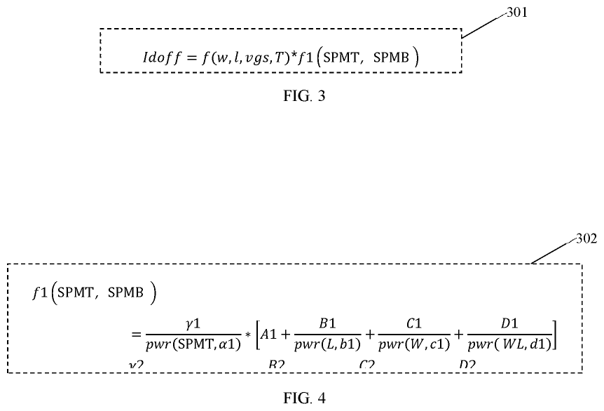

Referring to FIG. 2, it shows a layout of a semiconductor device of an embodiment of the present application: referring to FIG. 3, it shows a device leakage current model 301 of an embodiment of the present application: referring to FIG. 4, it shows a first function of a device leakage current model 302 of an embodiment of the present application: and the device leakage current model of an embodiment of the present application is used for simulating the leakage current of a semiconductor device, a first metal gate 202 is used for the gate structure of the semiconductor device, and the first metal gate 202 has a metal function layer with first conductive type.

The leakage current of the device leakage current model is formed by multiplying a main function by a first function.

The first function is a function formed by the metal gate boundary proximity effect parameters of the semiconductor device for modeling the influence of the metal gate boundary proximity effect on the leakage current.

Referring to FIG. 2, in the embodiment of the application, the metal gate boundary proximity effect parameters include a first spacing SPMT and a second spacing SPMB.

The semiconductor device is formed in a first active region 201, the circumference of which is field oxide, such as shallow trench isolation (STI).

The gate structure of the semiconductor device further includes a gate dielectric layer at the bottom of the first metal gate 202, the gate dielectric layer including a gate oxide layer or a high dielectric constant layer.

A channel region 203 is formed in the first active region 201 covered by the first metal gate 202.

The channel region 203 includes a first length edge, a second length edge and two width edges. The source and drain regions of the semiconductor device would be formed in a self-aligning manner in the first active region 201 at both sides of the first metal gate 202, and the length direction of the channel region 203 is the direction from the source region to the drain region.

The length direction of the first metal gate 202 is the same as the width edge direction of the channel region 203.

The first metal gate 202 further extends along the length direction at both sides into the first active region 201, and the first metal gate 202 has a first boundary 2041 and a second boundary 2042 outside the first active region 201.

The first boundary 2041 is the boundary between the first conductive type metal work function layer of the first metal gate 202 and a second conductive type metal work function layer of a second adjacent metal gate.

The second boundary 2042 is the boundary between the first conductive type metal work function layer of the first metal gate 202 and a second conductive type metal work function layer of a second adjacent metal gate. In FIG. 2, the formation area of the first conductive type metal work function layer of the first metal gate 202 is shown by a dashed box 204, the formation area of the second conductive type metal work function layer of the first adjacent metal gate is shown by a dashed box 205, and the formation area of the second conductive type metal work function layer of the second adjacent metal gate is by a dashed box 206.

The first boundary 2041 is adjacent to the first length edge, and the first spacing SPMT is the distance between the first boundary 2041 and the first length edge.

The second boundary 2042 is adjacent to the second length edge, and the second spacing SPMB is the distance between the second boundary 2042 and the second length edge.

The parameters of the first function further include a length L and a width W of a channel region.

In embodiments of the present application, the main function of the device leakage current model is a GIDL leakage current function; and the parameters of the GIDL leakage current function include: the width and length of the channel region, a gate source voltage and a temperature.

Referring to FIG. 3, in an embodiment of the present application, the equation of the leakage current of the device leakage current model is

$$Idoff = f ( w , l , vgs , T ) * f 1 ( SPMT , SPMB ) \qquad ( 2 )$$

Idoff indicates the leakage current,
where Idoff indicates the device leakage current, mainly the GIDL leakage current,
the same as equation (1), f( ) indicates the main function, that is, the function of the GIDL leakage current, w indicates the width of the channel region of the semiconductor device, l indicates the length of the channel region of the semiconductor device, vgs indicates the gate source voltage of the semiconductor device, and T indicates the operating temperature of the semiconductor device. It can be seen that w, l, vgs, T are related to the structural parameters of the semiconductor device itself.

Referring to FIG. 4, the equation of the first function is

$$( 3 )$$

$$f 1 ( SPMT , SPMB ) = \frac{γ 1}{pwr ( SPMT , α1 )} * [ A 1 + \frac{B 1}{pwr ( L , b 1 )} + \frac{C 1}{pwr ( W , c 1 )} + \frac{D 1}{pwr ( W * L , d 1 )} ] + \frac{γ 2}{pwr ( SPMB , α2 )} * [ A 2 + \frac{B 2}{pwr ( L , b 2 )} + \frac{C 2}{pwr ( W , c 2 )} + \frac{D 2}{pwr ( W * L , d 2 )} ] ;$$

where f1 ( ) indicates the first function; pwr ( ) indicates a power function;
SPMT indicates the first spacing SPMT, and SPMB indicates the second spacing SPMB;
W indicates the width of the channel region, and Z indicates the length of the channel region; and
γ1, α1, A1, B1, b1, C1, c1, D1, d1, γ2, α2, A2, B2, b2, C2, c2, D2, d2 are all fitting parameters.

In the embodiment of the application, each of the fitting parameters of the first function is obtained by performing parameter fitting for a leakage current curve formed by the device leakage current model and an actual measured leakage current curve by varying the first spacing SPMT and the second spacing SPMB, provided that the main function remains unchanged.

The first spacing SPMT and the second spacing SPMB are modified in a layout design.

In the embodiment of the present application, on the basis of an original device leakage current model, i.e., the main function, a function related to MBE size change is introduced in the original leakage model in view of the influence of the MBE size change on the device leakage current, thus including the influence of the MBE size change on a leakage current for a device. That facilitates a designer to consider the influence of the MBE size change on the device during circuit design, enabling the better applicability of the new leakage current model.

In the embodiment of the present application, when the MBE parameter is changed, the influence of such change on the leakage current can be accurately simulated by adding a product term consisting of a first function, a function formed by MBE parameters of a semiconductor device, on the basis of the main function of the leakage current of the device leakage current model. Thus, in the embodiment of the present application, the influence of the MEB effect on the leakage current can be simulated, thus improving the model fitting accuracy.

The MBE parameters of the embodiment of the present application are mainly MEB sizes, i.e., the first spacing SPMT and the second spacing SPMB, and thus, the embodiment of the present application can achieve more accurate modeling of the leakage current for various MBE sizes and can better reflect the actual circuit characteristics of the device.

The application can also achieve a more reasonable layout design based on the device leakage current model.

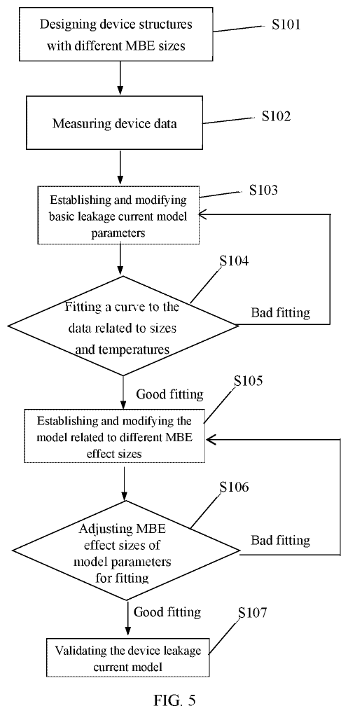

Referring to FIG. 5, it is a flow chart of the method for extracting a device leakage current model of the embodiment of the present application: in the method, the device leakage current model simulates the leakage current of the semiconductor device, the gate structure of the semiconductor device has a first metal gate 202, and the first metal gate 202 has a metal work function layer of the first conductive type: and the method includes the following steps:

step I. setting the leakage current of the device leakage current model to be formed by multiplying a main function by a first function.

The first function is a function formed by the MBE parameters of the semiconductor device for modeling the influence of the MBE effect on the leakage current.

Thereafter, the method of the embodiment of the present application further includes step S101 and step S102 shown in FIG. 5.

In step S101, device structures with different MBE sizes are designed. Referring to FIG. 2, the MBE sizes can be changed by a layout design, i.e., changing the first spacing SPMT and the second spacing SPMB shown in FIG. 2.

After that, the semiconductor device is fabricated on a semiconductor substrate according to the layout design.

Step S102 is included: measuring device data. Step S102 enables measurement of structural parameters and electrical parameters of the semiconductor device.

Step II includes: performing parameter fitting for the main function by including the semiconductor device that is not influenced by MBE effects.

Step II is achieved by cyclic performing of step S103 and step S104 in FIG. 5.

In step S103, basic leakage current model parameters are established and modified.

In the method of the embodiment of the present application, the basic leakage current model is the main function which is the GIDL leakage current function, and the parameters include: the width and length of the channel region, a gate source voltage and a temperature, which are measurable parameters. The main function is: f (w, l, vgs, T), where w indicates the width of the channel region of the semiconductor device, l indicates the length of the channel region of the semiconductor device, vgs indicates the gate source voltage of the semiconductor device, and T indicates the operating temperature of the semiconductor device. It can be seen that w, l, vgs, T are related to the structural parameters of the semiconductor device itself, which can be obtained by measurement. Fitting parameters would also set in f (w, l, vgs, T).

In step S104, curve fitting is performed for the data related to sizes and temperature, i.e., fitting is performed on the basis of w, l, vgs, T to obtain the fitting parameters of f(w, l, vgs, T. If the fitting is poor, the fitting parameters of (w, l, vgs, T) are modified until the fitting is good, then to obtain the main function, i.e., f (w, l, vgs, T). After the fitting is completed, a subsequent step S105 is performed.

In step III, fitting is performed for the first function to obtain the fitted parameters of the first function by changing the MBE parameters of the semiconductor device, provided that the main function remains unchanged.

In the method of the embodiment of the present application, the fitting of the model curve related to the MBE effect mainly includes:
each of the fitting parameters of the first function is obtained by performing parameter fitting for a leakage current curve formed by the device leakage current model and an actual measured leakage current curve by varying the first spacing SPMT and the second spacing SPMB, provided that the main function remains unchanged.

The first spacing SPMT and the second spacing SPMB are modified in a layout design, i.e. such modification is implemented in the previous step S101.

Step III is achieved by cyclic performing of step S105 and step S106 in FIG. 5.

Step S105 is: establishing and modifying the model related to different MBE effect sizes. In the method of the embodiment of the present application, referring to FIG. 2, the metal gate boundary proximity effect parameters include a first spacing SPMT and a second spacing SPMB.

The semiconductor device is formed in a first active region 201 and a channel region 203 is formed in the first active region 201 covered by the first metal gate 202.

The channel region 203 includes a first length edge, a second length edge and two width edges.

The length direction of the first metal gate 202 is the same as the width edge direction of the channel region 203.

The first metal gate 202 further extends along the length direction at both sides into the first active region 201, and the first metal gate 202 has a first boundary 2041 and a second boundary 2042 outside the first active region 201.

The first boundary 2041 is the boundary between the first conductive type metal work function layer of the first metal gate 202 and a second conductive type metal work function layer of a second adjacent metal gate.

The second boundary 2042 is the boundary between the first conductive type metal work function layer of the first metal gate 202 and a second conductive type metal work function layer of a second adjacent metal gate.

The first boundary 2041 is adjacent to the first length edge, and the first spacing SPMT is the distance between the first boundary 2041 and the first length edge.

The second boundary 2042 is adjacent to the second length edge, and the second spacing SPMB is the distance between the second boundary 2042 and the second length edge.

The parameters of the first function further include the length and width of the channel region.

The equation of the first function is:

$$( 3 )$$

$$f 1 ( SPMT , SPMB ) = \frac{γ 1}{pwr ( SPMT , α1 )} * [ A 1 + \frac{B 1}{pwr ( L , b 1 )} + \frac{C 1}{pwr ( W , c 1 )} + \frac{D 1}{pwr ( W * L , d 1 )} ] + \frac{γ 2}{pwr ( SPMB , α2 )} * [ A 2 + \frac{B 2}{pwr ( L , b 2 )} + \frac{C 2}{pwr ( W , c 2 )} + \frac{D 2}{pwr ( W * L , d 2 )} ] ;$$

where f1 ( ) indicates the first function: pwr ( ) indicates a power function;
SPMT indicates the first spacing SPMT, and SPMB indicates the second spacing SPMB;
W indicates the width of the channel region, and L indicates the length of the channel region; and
γ1, α1, A1, B1, b1, C1, c1, D1, d1, γ2, α2, A2, B2, b2, C2, c2, D2, d2 are all fitting parameters.

Step S106 is: performing parameter fitting by adjusting the model parameters of the MBE effect size, i.e., performing parameter fitting for the model by adjusting the MBE size.

If the fitting result in step S106 is poor, then return to step S105 to modify the values of each fitting parameter, and then, step S106 is performed: and if the result of step S106 is good, then the device leakage current modeling is performed.

In the method of the embodiment of the present application, after step III is completed, it also includes the step of validating the device leakage current model, i.e., performing step S107 of FIG. 5: validating the device leakage current model.

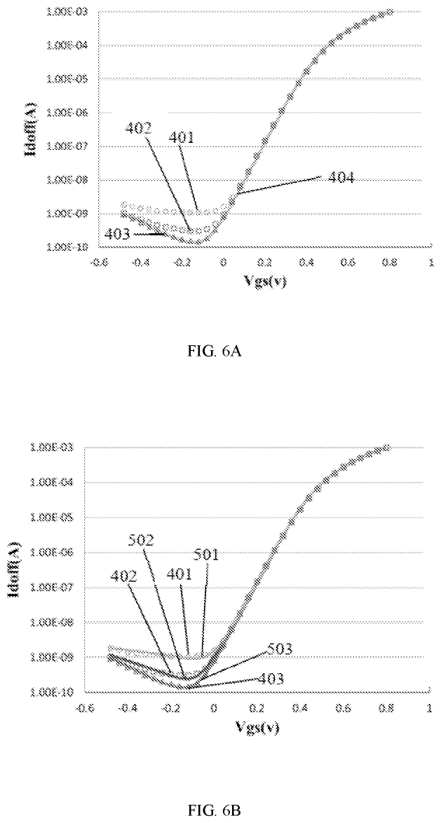

Referring to FIG. 6A, it shows leakage current fitting curves using the existing device leakage current model: in FIG. 6A, curves 401, 402 and 403 are test curves of the leakage currents of the semiconductor devices corresponding to three MBE sizes, i.e., SPMT and SPMB which have the test conditions of: a source to drain leakage voltage vds equal to 0.8 V, a source to base substrate voltage Vbs equal to 0 V, and Idoff which is a gate current Id_Vg at off position.

Curve 404 is a leakage current fitting curve using the existing device leakage current model. It can be seen that, with the same fitted values of the leakage currents of the semiconductor devices corresponding to the three MBE sizes, the existing device leakage current model cannot simulate correctly the influence of the MBE effects on the leakage current.

Referring to FIG. 6B, it shows leakage current fitting curves using the device leakage current model according to the embodiment of the present application: herein the curves 401 to 403 are the same MBE influenced curves as those in FIG. 6A; however curves 501, 502 and 503 are leakage current curves of semiconductor devices with three MBE sizes obtained by fitting via the device leakage current model of an embodiment of the present application. It can be seen that curves 501 and 401, curves 502 and 402, and curves 503 and 403 all have good degrees of fitting. Thus, the device leakage current model of the embodiment of the present application enables good simulation of the influence of the MBE size on the leakage current, demonstrating improved simulation accuracy.

In the method of the embodiment of the present application, in order to characterize the influence, on the device leakage current model, of the change of the distance between different metal boundaries and a device, i.e., the size corresponding to the MBE effect, also i.e., the MBE size, a designed layout associated with the influence is added. In the added designed layout, the following parameters should be included: 1. drawing metal boundaries with different distances from a channel of a device body, i.e., the metal boundaries for different MBE sizes, such as SPMB, and SPMT: and 2. fixing the distance of one edge, while changing the distance between other edges of the metal boundaries and the device. Then, the wafer obtained according to the designed layout is measured, and the measured data is analyzed. After a conventional device leakage current model is fitted, the function coefficients associated with different MBE sizes (SPMT, SPMB), i.e., SPMT and SPMB, are started to be adjusted, so that the leakage current models associated with the different MBE sizes (SPMT, SPMB) can be obtained. By comparing FIG. 6A with FIG. 6B, it can be seen that FIG. 6B shows a better fitting result than FIG. 6A. By simulation via the model, a designer can then know the performance of the device with different distances of metal boundaries from the device. Thus, such a factor can be taken into consideration when starting the design, thus enabling the better presentation of the actual device characteristics by the new model.

The detailed description of the application has been provided above by means of specific embodiments, but it is not intended to limit the application. Without departing from the principle of the application, those skilled in the art can make many variations and improvements which are also within the scope of protection of the application.

What is claimed is:

1. A device model for simulating a leakage current in a semiconductor device, wherein the semiconductor device comprises:
a gate structure, a first metal gate, and a first metal function layer of a first conductive type;
wherein the leakage current of the device model is formed by multiplying a main function by a first function; and
wherein the first function comprises metal gate boundary proximity effect parameters for modeling influence of the metal gate boundary proximity effect on the leakage current of the semiconductor device.

2. The device model according to claim 1, wherein the metal gate boundary proximity effect parameters comprise a first spacing and a second spacing;
wherein the semiconductor device is formed in a first active region, and a channel region is formed in the first active region under the first metal gate;
wherein the channel region comprises a first length edge, a second length edge and two width edges;
wherein a length direction of the first metal gate is a same as a width edge direction of the channel region;
wherein the first metal gate extends along the length direction at both sides into the first active region, and wherein the first metal gate comprises a first boundary and a second boundary outside the first active region;
wherein the first boundary is located between the first metal work function layer of the first conductive type of the first metal gate and a second metal work function layer of a second conductive type of a first adjacent metal gate;
wherein the second boundary is located between the first metal work function layer of the first conductive type of the first metal gate and the second metal work function layer of the second conductive type of a second adjacent metal gate;
wherein the first boundary is adjacent to the first length edge, and wherein the first spacing is a distance between the first boundary and the first length edge; and
wherein the second boundary is adjacent to the second length edge, and wherein the second spacing is a distance between the second boundary and the second length edge.

3. The device model according to claim 2, wherein parameters of the first function further comprise a length a width of the channel region.

4. The device model according to claim 3, wherein an equation of the first function comprises:
$$f 1 ( SPMT , SPMB ) = \frac{γ 1}{pwr ( SPMT , α1 )} * [ A 1 + \frac{B 1}{pwr ( L , b 1 )} + \frac{C 1}{pwr ( W , c 1 )} + \frac{D 1}{pwr ( W * L , d 1 )} ] + \frac{γ 2}{pwr ( SPMB , α2 )} * [ A 2 + \frac{B 2}{pwr ( L , b 2 )} + \frac{C 2}{pwr ( W , c 2 )} + \frac{D 2}{pwr ( W * L , d 2 )} ] ;$$
where f1 ( ) indicates the first function; and wherein pwr ( ) indicates a power function;
wherein:
SPMT indicates the first spacing, and SPMB indicates the second spacing;
W indicates the width of the channel region, and L indicates the length of the channel region; and
γ1, α1,A1, B1, b1, C1,c1,D1,d1, γ2, α2, A2, B2, b2, C2, c2, D2, d2 are all fitting parameters of the first function.

5. The device model according to claim 4, wherein the main function of the device model describes a gate-induced drain leakage (GIDL) leakage current function; and wherein parameters of the GIDL leakage current function comprise:
the width and length of the channel region, a gate source voltage and a temperature.

6. The device model according to claim 5, wherein each of the fitting parameters of the first function are obtained by performing parameter fitting for a leakage current curve formed by the device model and a set of actual measured leakage current data by varying the first spacing and the second spacing, provided that the main function remains unchanged.

7. The device model according to claim 6, wherein the first spacing and the second spacing are modified in a layout design.

8. A method for extracting a device model for simulating a leakage current in a semiconductor device, wherein the semiconductor device comprises a gate structure, a first metal gate, and a first metal function layer of the first conductive type;
wherein the method comprises steps of:
step I: forming the leakage current of the device model by multiplying a main function by a first function,
wherein the first function comprises metal gate boundary proximity effect parameters for modeling influence of the metal gate boundary proximity effect on the leakage current of the semiconductor device;
step II: performing parameter fitting for the main function by using a semiconductor device unaffected by the metal gate boundary proximity effect; and
step III: performing parameter fitting for the first function to obtain the fitted parameters of the first function by varying the metal gate boundary proximity effect parameters of the semiconductor device while keeping the main function unchanged.

9. The method for extracting the device model according to claim 8, wherein the metal gate boundary proximity effect parameters comprise a first spacing and a second spacing;
wherein the method further comprises:
forming the semiconductor device in a first active region, and forming a channel region in the first active region under by the first metal gate;
wherein the channel region comprises a first length edge, a second length edge and two width edges;
wherein a length direction of the first metal gate is a same as a width edge direction of the channel region;
wherein the first metal gate further extends along the length direction at both sides into the first active region, and wherein the first metal gate has a first boundary and a second boundary outside the first active region;
the second boundary is between the first metal work function layer of the first conductive type of the first metal gate and wherein the first boundary is located between the first metal work function layer of the first conductive type of the first metal gate and the second metal work function layer of the second conductive type of a first adjacent metal gate; wherein the second boundary is located between the first metal work function layer of the first type conductive type of the first metal gate and the second metal work function layer of the second conductive type of a second adjacent metal gate;
wherein the first boundary is adjacent to the first length edge, and the first spacing is the distance between the first boundary and the first length edge; and
wherein the second boundary is adjacent to the second length edge, and the second spacing is a distance between the second boundary and the second length edge.

10. The method for extracting the device model according to claim 9, wherein the fitting parameters of the first function further comprise the length and width of the channel region.

11. The method for extracting the device model according to claim 10, wherein an equation of the first function is:
$$f 1 ( SPMT , SPMB ) = \frac{γ 1}{pwr ( SPMT , α1 )} * [ A 1 + \frac{B 1}{pwr ( L , b 1 )} + \frac{C 1}{pwr ( W , c 1 )} + \frac{D 1}{pwr ( W * L , d 1 )} ] + \frac{γ 2}{pwr ( SPMB , α2 )} * [ A 2 + \frac{B 2}{pwr ( L , b 2 )} + \frac{C 2}{pwr ( W , c 2 )} + \frac{D 2}{pwr ( W * L , d 2 )} ] ;$$
wherein
f1 ( ) indicates the first function; pwr ( ) indicates a power function;
SPMT indicates the first spacing, and SPMB indicates the second spacing;
W indicates the width of the channel region, and L indicates the length of the channel region; and
γ1, α1, A1, B1, b1, C1, c1, D1, d1, γ2, α2, A2, B2, b2, C2, c2, D2, d2 are all fitting parameters of the first function.

12. The method for extracting the device model according to claim 11, wherein the main function of the device model is a GIDL leakage current function; and wherein parameters of the GIDL leakage current function comprise:
the width and length of the channel region, a gate to source voltage and a temperature.

13. The method for extracting the device model according to claim 12, wherein in step III, each of the fitting parameters of the first function is obtained by performing parameter fitting for a leakage current curve formed by the device model and a set of actual measured leakage current data by varying the first spacing and the second spacing.

14. The method for extracting the device model according to claim 13, wherein the first spacing and the second spacing are modified in a layout design.

15. The method for extracting the device model according to claim 8, wherein after the step III is completed, a step of validating the device model is also comprised.
